(19) United States
(12) Patent Application Publication
(10) Pub. No.: US 2018/0160064 A1
(43) Pub. Date: Jun. 7, 2018

(54) SOLID-STATE IMAGING DEVICE AND ELECTRONIC APPARATUS

(71) Applicant: SONY CORPORATION, TOKYO (JP)

(72) Inventor: KUMIKO MAHARA, FUKUOKA (JP)

(21) Appl. No.: 15/576,385

(22) PCT Filed: Jun. 10, 2016
(86) PCT No.: PCT/JP2016/067322

§ 371 Date: Nov. 22, 2017

(30) Foreign Application Priority Data
Jun. 26, 2015 (JP) 2015-128879

(51) Int. Cl. H04N 5/378; H04N 5/369; H04N 5/367

(52) U.S. Cl. CPC H04N 5/378; H04N 5/367; H04N 5/3696

(57) ABSTRACT

The present disclosure relates to a solid-state imaging device and an electronic apparatus that are capable of validating data at the time of vertical addition even when special pixels exist. In a case of A, when, for example, a special pixel S in the second row and an imaging pixel GR in the fourth row are to be added and the special pixel S is selected, the addition of the imaging pixel GR is masked so that information on the special pixel S can be output. In a case of B, when, for example, a special pixel S in the second row and an imaging pixel GR in the fourth row are to be added and the imaging pixel GR is selected, the addition of the special pixel S is masked so that information on the imaging pixel GR can be output. The present disclosure is applicable, for example, to a CMOS solid-state imaging device that is used as an image pickup device such as a camera.

### TECHNICAL FIELD

The present disclosure relates to a solid-state imaging device and an electronic apparatus, and more particularly, to a solid-state imaging device and an electronic apparatus that are capable of validating data at the time of vertical addition even when special pixels exist.

### BACKGROUND ART

An imaging element is known which is configured so that pixels disposed to form the imaging element include special pixels such as image plane phase difference detection pixels. Such a type of imaging element does not require a dedicated automatic sensor and is capable of performing high-speed phase difference autofocusing (refer to PTL 1). It is to be noted that, as opposed to the above-mentioned special pixels, pixels used for general imaging are referred to as imaging pixels.

### CITATION LIST

### Patent Literature

[PTL 1]

JP 2014-109767A

### SUMMARY

### Technical Problem

However, at the time of vertical addition, it can merely perform the same addition on same-color pixels in the same row. Therefore, when special pixels exist, they are added to imaging pixels so that information on the special pixels and information on the imaging pixels are both corrupted.

The present disclosure has been made in view of the above circumstances and is capable of validating data at the time of vertical addition even when special pixels exist.

### Solution to Problem

A solid-state imaging device according to an aspect of the present technology includes pixels and a vertical addition circuit. The pixels are arrayed regularly in a two-dimensional manner. When vertical addition is to be performed and one of pixels to be vertically added is a special pixel having a function other than imaging, the vertical addition circuit outputs only either one of the pixels to be vertically added.

When one of the pixels to be vertically added is the special pixel, the vertical addition circuit may mask a pixel to be not output and output either one of the pixels to be vertically added.

When the pixels to be vertically added are both imaging pixels having an imaging function, the vertical addition circuit may perform vertical addition.

Before performing vertical addition, the vertical addition circuit may horizontally divide into at least a circuit where the special pixel is disposed and a circuit where the special pixel is not disposed.

For a row where the special pixel is disposed, the vertical addition circuit may perform vertical addition on a circuit where the special pixel is not disposed, and may select, as an output target, only a circuit where the special pixel is disposed, and output only either one of the pixels to be vertically added.

For a row where the special pixel is not disposed, the vertical addition circuit may perform vertical addition on a circuit where the special pixel is not disposed and on a circuit where the special pixel is disposed.

An electronic apparatus according to an aspect of the present technology includes a solid-state imaging device, a signal processing circuit, and an optical system. The solid-state imaging device includes pixels and a vertical addition circuit. The pixels are arrayed regularly in a two-dimensional manner. When vertical addition is to be performed and one of pixels to be vertically added is a special pixel having a function other than imaging, the vertical addition circuit outputs only either one of the pixels to be vertically added. The signal processing circuit processes an output signal that is output from the solid-state imaging device. The optical system allows incident light to enter the solid-state imaging device.

According to an aspect of the present technology, when pixels arrayed regularly in a two-dimensional manner are to be vertically added and one of the pixels to be vertically added is a special pixel having a function other than imaging, only either one of the pixels to be vertically added is output.

### Advantageous Effect of Invention

The present technology is capable of validating data at the time of vertical addition even when special pixels exist.

It is to be noted that the advantages described in the present specification are merely illustrative and not restrictive. The present technology is not limited to the advantages described in the present specification and can provide additional advantages.

### BRIEF DESCRIPTION OF DRAWINGS

FIG. 1 is a block diagram illustrating an exemplary outline configuration of a solid-state imaging device to which the present technology is applied.

FIG. 2 is a diagram illustrating a vertical addition operation that is performed when the same addition is performed on each row.

FIG. 3 is a diagram illustrating a vertical addition operation that is performed when the same addition is performed on each row.

FIG. 4 is a diagram illustrating a vertical addition operation according to the present technology.

FIG. 5 is a diagram illustrating an exemplary configuration of a vertical addition circuit to which the present technology is applied.

FIG. 6 is a block diagram illustrating an exemplary configuration of a logic circuit to which the present technology is applied.

FIG. 7 is a diagram illustrating advantages.

FIG. 8 is a diagram illustrating advantages.

FIG. 9 is a diagram illustrating advantages.

FIG. 10 is a diagram illustrating an exemplary configuration of an addition circuit that is used in a case where disposition of special pixels varies from one line to another.

FIG. 11 is a diagram illustrating structures of the solid-state imaging device to which the present technology is applied.

FIG. 12 is a block diagram illustrating an exemplary configuration of an electronic apparatus to which the present technology is applied.

### DESCRIPTION OF EMBODIMENTS

Embodiments for implementing the present disclosure (hereinafter referred to as the embodiments) will now be described. It is to be noted that he description will be given in the following order.
1. First Embodiment
2. Second Embodiment (Exemplary Uses of Image Sensor)
3. Third Embodiment (Example of Electronic Apparatus)

### 1. First Embodiment

<Exemplary Outline Configuration of Solid-State Imaging Device>

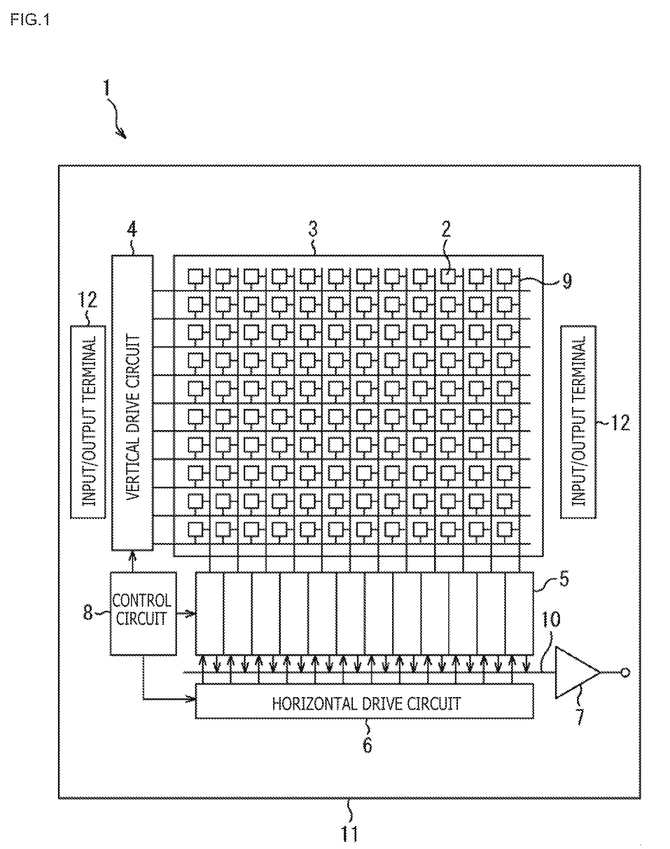

FIG. 1 illustrates an exemplary outline configuration of a CMOS (Complementary Metal Oxide Semiconductor) solid-state imaging device that is applied to respective embodiments of the present technology.

As illustrated in FIG. 1, a solid-state imaging device (element chip) 1 includes a pixel region (so-called imaging region) 3 and a peripheral circuit section. The pixel region 3 is formed by regularly arraying a plurality of pixels 2, which includes a photoelectric conversion element, in a two-dimensional manner over a semiconductor substrate 1 (e.g., silicon substrate).

The pixels 2 each include a photoelectric conversion element (e.g., photodiode) and a plurality of pixel transistors (so-called MOS transistors). The plurality of pixel transistors may include, for example, three transistors, namely, a transfer transistor, a reset transistor, and an amplifier transistor. Alternatively, the pixel transistors may include four transistors by adding a selection transistor as the fourth transistor. An equivalent circuit of each pixel 2 (unit pixel) is similar to a common one and will not be described in detail.

Further, the pixels 2 may have a pixel sharing structure. The pixel sharing structure is formed of a plurality of photodiodes, a plurality of transfer transistors, one floating diffusion to be shared, and one each of the other pixel transistors to be shared. The photodiodes are photoelectric conversion elements.

The peripheral circuit section includes a vertical drive circuit 4, a column signal processing circuit 5, a horizontal drive circuit 6, an output circuit 7, and a control circuit 8.

The control circuit 8 receives an input clock and data designating, for example, an operating mode, and also outputs data including, for example, internal information on the solid-state imaging device 1. More specifically, based on a vertical synchronization signal, a horizontal synchronization signal, and a master clock, the control circuit 8 generates a clock signal and a control signal that serve as an operation reference for the vertical drive circuit 4, the column signal processing circuit 5, and the horizontal drive circuit 6. The control circuit 8 inputs these signals to the vertical drive circuit 4, the column signal processing circuit 5, and the horizontal drive circuit 6.

The vertical drive circuit 4 is formed, for example, of a shift register in order to select a pixel drive wiring, supply a pulse to the selected pixel drive wiring for driving pixels 2, and drive the pixels 2 in units of a row. More specifically, the vertical drive circuit 4 sequentially performs a selective vertical scan on each pixel 2 in the pixel region 3 in units of a row, and supplies, to the column signal processing circuit 5 through a vertical signal line 9, a pixel signal based on a signal electrical charge that is generated by the photoelectric conversion element of each pixel 2 in accordance with the amount of received light.

The column signal processing circuit 5 is disposed, for example, in each column of the pixels 2 in order to perform noise removal or other signal processing on signals output from one row of pixels 2 in units of a pixel column. More specifically, the column signal processing circuit 5 performs signal processing, such as CDS (Correlated Double Sampling) for removing fixed-pattern noise unique to the pixels 2, signal amplification, or A/D (Analog/Digital) conversion. A horizontal selector switch (not depicted) is connected between a horizontal signal line 10 and the output stage of the column signal processing circuit 5.

The horizontal drive circuit 6 is formed, for example, of a shift register in order to sequentially select a plurality of pieces of the column signal processing circuit 5 by sequentially outputting a horizontal scanning pulse and output a pixel signal to the horizontal signal line 10 from each of the pieces of the column signal processing circuit 5.

The output circuit 7 performs signal processing on signals that are sequentially supplied from each of the pieces of the column signal processing circuit 5 through the horizontal signal line 10, and outputs the processed signals. In some cases, the output circuit 7 may perform, for example, buffering only. In some other cases, the output circuit 7 may perform, for example, black level adjustment, column variation correction, and various digital signal processing operations.

An input/output terminal 12 is provided to exchange signals with the outside.

<Vertical Addition Operation>

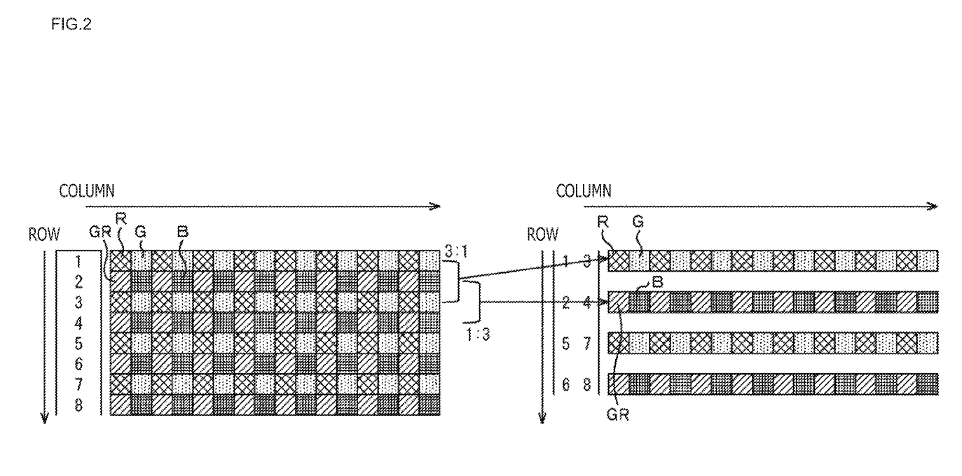

FIG. 2 is a diagram illustrating a vertical addition operation that is performed when the same addition is performed on each row. It is to be noted that, here, the term “vertical addition” denotes capacitance addition for adding electrical charges together, CN (counter) addition at the time of A/D conversion, logic or other line addition, and all of them.

An image in the example of FIG. 2 depicts an operation for vertical 2 addition of pixels 2. In this example, the same addition is performed for each row when vertical addition is performed to add data in each row.

More specifically, in the example of FIG. 2, pixel R data in the first row and pixel R data in the third row of the same column are added on a 3:1 basis, and data obtained upon addition is output as data in the first and third rows of the same column. Similarly, pixel GR data in the second row and pixel R data in the fourth row of the same column are added on a 3:1 basis, and data obtained upon addition is output as data in the first and third rows of the same column.

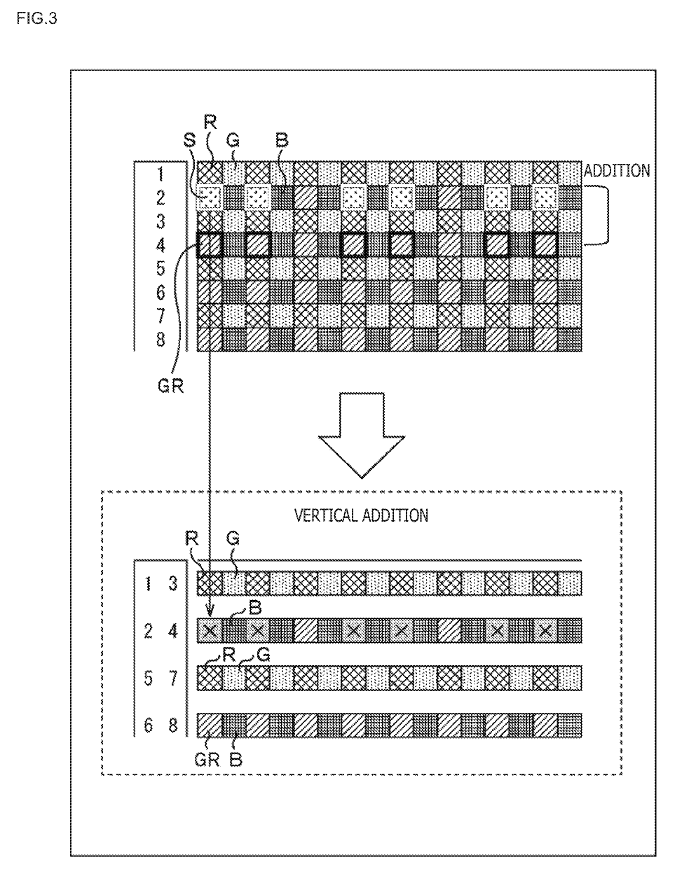

In some cases, however, the pixels 2 may include a special pixel S such as an image plane phase difference pixel. It is to be noted that, as opposed to a special pixel, a pixel used for imaging is hereinafter referred to as an imaging pixel. If a vertical addition method indicated in FIG. 2 is used in a situation where a special pixel S is disposed among the pixels 2, the special pixel S in the second row is added to an imaging pixel GR in the fourth row as illustrated in FIG. 3. Thus, such an addition corrupts both information on the special pixel S and information on the imaging pixel GR.

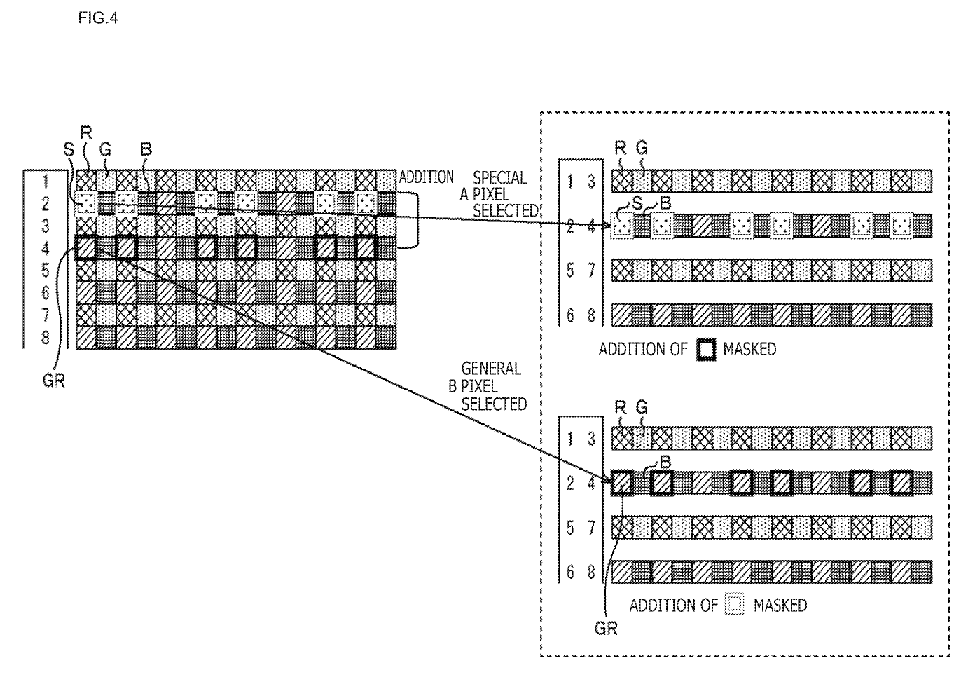

In view of the above circumstances, the present technology masks pixel information on either the special pixel S or the imaging pixel GR and prevents the masked pixel information from being added, as illustrated in FIG. 4.

In the case of A in FIG. 4, when, for example, a special pixel S in the second row and an imaging pixel GR in the fourth row are to be added and the special pixel S is selected, the addition of the imaging pixel GR is masked so that the information on the special pixel S is output.

In the case of B in FIG. 4, when, for example, a special pixel S in the second row and an imaging pixel GR in the fourth row are to be added and the imaging pixel GR is selected, the addition of the special pixel S is masked so that the information on the imaging pixel GR is output.

Consequently, either the special pixel S or the imaging pixel GR can be selected and flexibly output without corrupting necessary information.

<Vertical Addition Circuit Configuration of Present Technology>

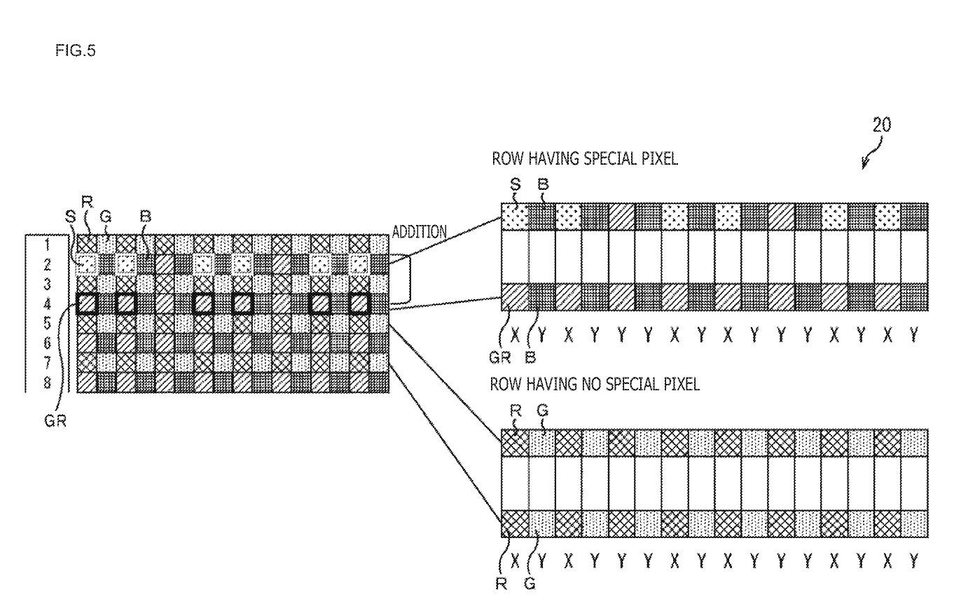

FIG. 5 is a diagram illustrating an exemplary configuration of a vertical addition circuit to which the present technology is applied. It is to be noted that FIG. 5 depicts an exemplary analog circuit, for example, for capacitance addition and counter addition.

In the example of FIG. 5, when a read operation is performed in the column direction, addition control is exercised with a vertical addition circuit 20 divided into circuits X and circuits Y. The number of pixels in the vertical addition circuit 20 is equal to the number of horizontal pixels. The circuits X include a special pixel S. The circuits Y include no special pixel S.

In the vertical addition circuit 20 depicted in FIG. 5, special pixels S are disposed in the first, third, seventh, and ninth columns of the second row. In this instance, therefore, the first, third, seventh, and ninth columns are regarded as the circuits X having a special pixel S, and the other columns are regarded as the circuits Y having no special pixel S.

For rows having a special pixel S, such as illustrated in the second and fourth rows, control is exercised so that the circuits Y perform an addition process, and that the circuits X mask either the special pixel S or the imaging pixel and do not perform addition (i.e., masks addition control).

Further, for rows having no special pixel S, such as illustrated in the fifth and seventh rows, control is exercised so that both the circuits X and the circuits Y perform an addition process.

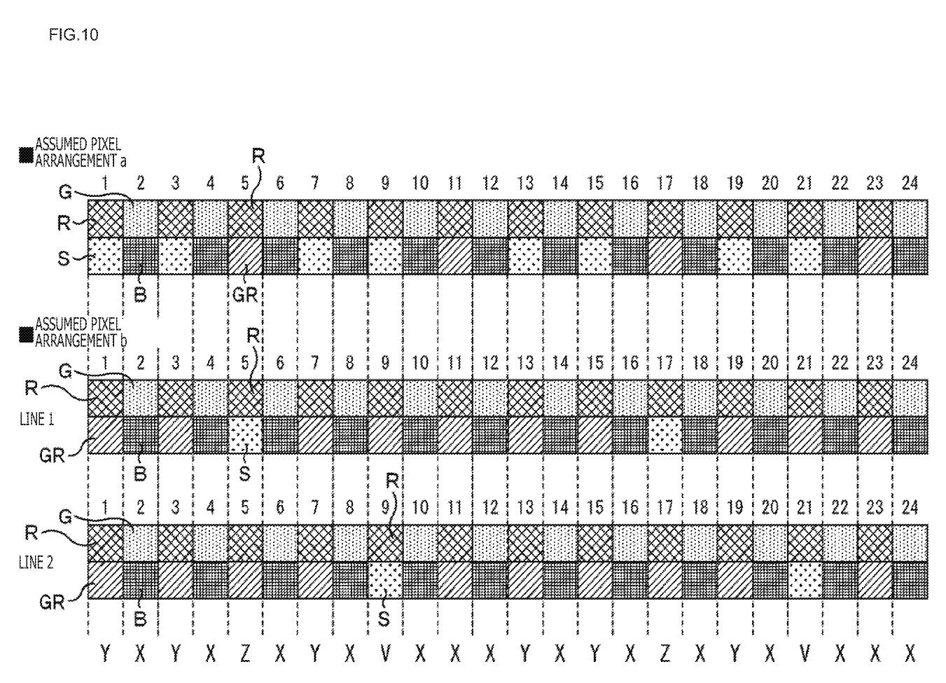

It is to be noted that, in the example of FIG. 5, the circuit is divided into two types of circuits, namely, the circuits X and the circuits Y. However, in a situation where the position of a special pixel S varies from one line to another depending on the arrangement of pixels, the circuit is divided into three or more types of circuits without being divided into two types of circuits, namely, the circuits X and the circuits Y. An example indicative of such a situation will be described later with reference to FIG. 10.

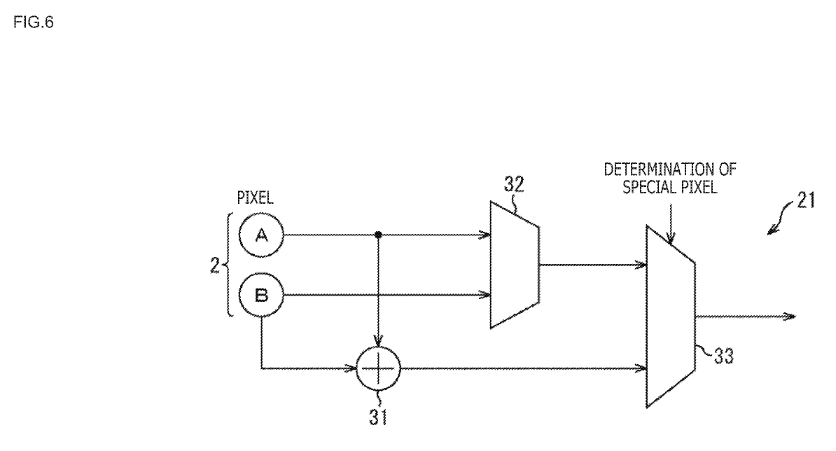

Further, the example of FIG. 5 depicts an exemplary configuration of an analog vertical addition circuit. However, the vertical addition circuit is also capable of performing logic addition depicted in FIG. 6.

<Logic Circuit>

FIG. 6 is a block diagram illustrating an exemplary configuration of a logic circuit to which the present technology is applied. It is to be noted that the logic circuit is more flexible than the analog circuit, but is characterized in that it consumes a considerable amount of power.

A logic circuit 21 depicted in FIG. 6 includes an adder 31, a selector 32, and a selector 33.

Information on two pixels, namely, pixel A and pixel B, is inputted to the adder 31 and to the selector 32. The adder 31 adds the information on pixel A and the information on pixel B, and outputs the result of addition to the selector 33.

The selector 32 receives information from, for example, the control circuit 8. The received information is structured so that addresses are grouped into a special pixel or an imaging pixel. In accordance with the received information (depending on whether a processing target is the information on a special pixel or the information on an imaging pixel), the selector 32 selects the information on either pixel A or pixel B, and outputs the selected information to the selector 33.

Depending on whether or not the information is on a special pixel, the selector 33 selects either information from the adder 31 or information from the selector 32, and outputs the result of selection to an output stage (not depicted).

As described above, the vertical addition circuit (vertical addition circuit or logic circuit) is configured to be able to output only either one of pixels. Therefore, the following advantages are obtained.

<Advantages of Present Technology>

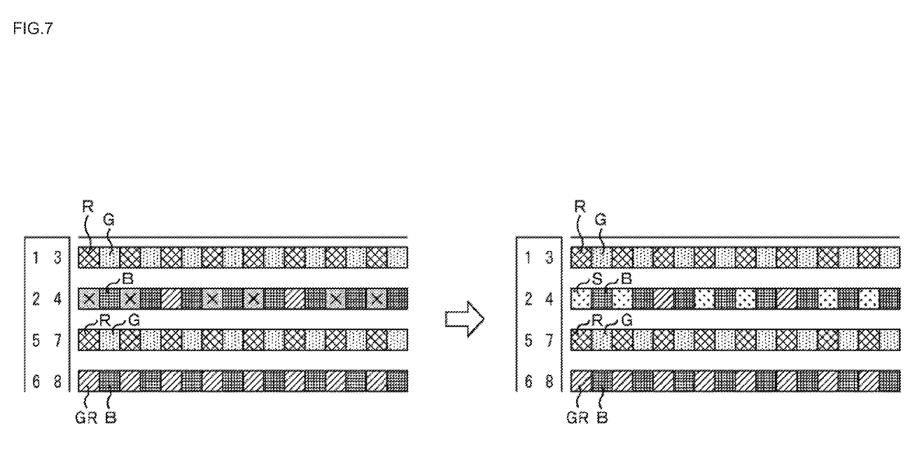

Advantages provided by the present technology will now be described with reference to FIGS. 7 to 9. For comparison purposes, FIGS. 7 to 9 are divided into a left portion and a right portion. The left portion illustrates vertical addition depicted in FIG. 2. The right portion illustrates vertical addition provided by the present technology.

In the case where vertical addition is performed as depicted in FIG. 2, the information on a special pixel is corrupted at the time of vertical addition as indicated in the left portion of FIG. 7. Meanwhile, the present technology is capable of operating by using a special pixel even at the time of vertical addition as indicated in the right portion of FIG. 7. The present technology is able to acquire, for example, information on an image plane phase even at the time of vertical addition. Consequently, an autofocusing operation for monitoring can be performed with reduced power consumption.

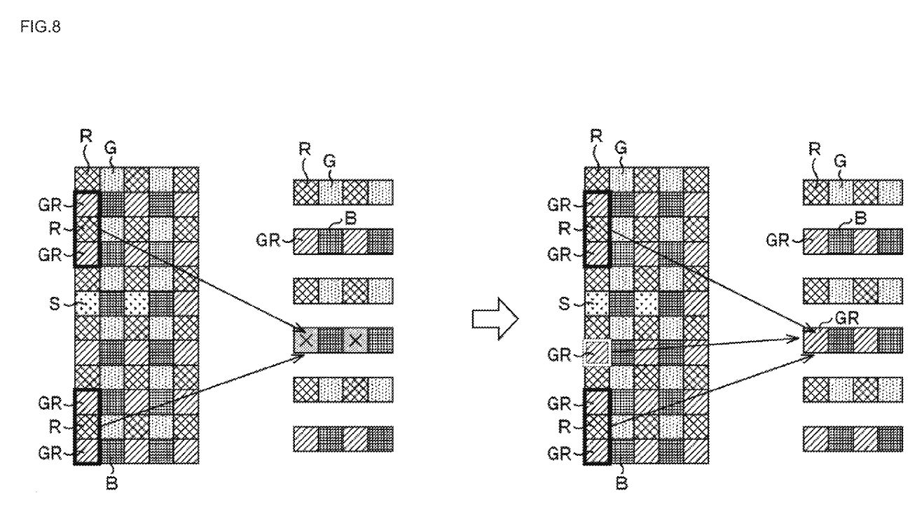

In the case where vertical addition is performed as depicted in FIG. 2, the information on a special pixel is corrupted at the time of vertical addition as indicated in the left portion of FIG. 8. Therefore, the defective pixel can only be interpolated from information on pixels located above and below the defective pixel. Meanwhile, as indicated in the right portion of FIG. 8, the present technology is able to acquire only the information (data) on a pixel to be added to a special pixel. Consequently, the present technology increases the accuracy of interpolation.

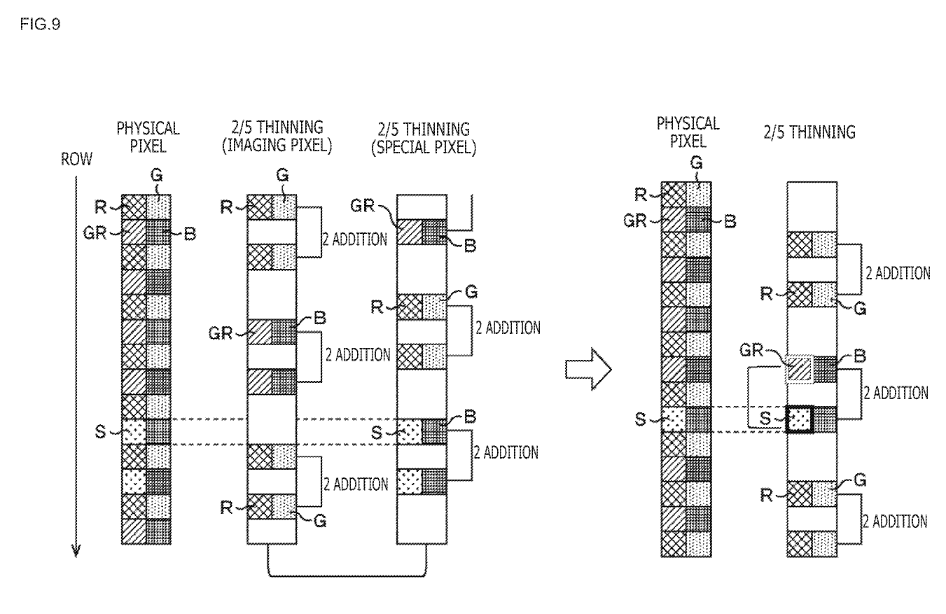

If the information on a special pixel and the information on an imaging pixel are added as indicated in the left portion of FIG. 9 in a situation where vertical addition is performed as depicted in FIG. 2, neither of two different pieces of information can be acquired. Therefore, it is necessary to read different rows when generating an imaging pixel output and a special pixel output. This makes it necessary to perform, for example, a process of transitioning between an imaging pixel output mode and a special pixel output mode. Thus, for example, a certain frame is discarded due, for instance, to a shutter change. The left portion of FIG. 9 sequentially depicts the physical arrangement of pixels in the example of FIG. 2, pixels read in the imaging pixel output mode for 2/5 thinning, and pixels read in the special pixel output mode for 2/5 thinning.

Meanwhile, as indicated in the right portion of FIG. 9, the present technology is capable of selectively masking either the information on a special pixel or the information on an imaging pixel. Therefore, a flexible operation can be performed, for example, in register communication.

<Vertical Addition Circuit Configuration of Present Technology>

FIG. 10 is a diagram illustrating an exemplary configuration of a vertical addition/capacitance addition circuit that is used in a case where the disposition of special pixels varies from one line to another.

Adopted is a configuration where one of two different pixel arrangements (assumed pixel arrangements a and b) is selectable for each user. The circuit is configured to be preliminarily divided into four types of circuits, namely, circuits X, circuits Y, circuits Z, and circuits V.

In the assumed pixel arrangement a of FIG. 10, the circuits X are addition circuits for an imaging pixel G and an imaging pixel B, the circuits Y are addition circuits for an imaging pixel R and a special pixel S, the circuits Z are addition circuits for an imaging pixel R and an imaging pixel GR, and the circuits V are addition circuits for an imaging pixel R and a special pixel S.

Consequently, for a row having a special pixel in the assumed pixel arrangement a, control is exercised so that the circuits X and the circuits Z perform an addition process, and that the circuits Y and the circuits V mask either a special pixel S or an imaging pixel and do not perform addition.

In line 1 of the assumed pixel arrangement b, the circuits X are addition circuits for an imaging pixel G and an imaging pixel B, the circuits Y are addition circuits for an imaging pixel R and an imaging pixel GR, the circuits Z are addition circuits for an imaging pixel R and a special pixel S, and the circuits V are addition circuits for an imaging pixel R and an imaging pixel GR.

Consequently, for a row having a special pixel in line 1, control is exercised so that the circuits X, the circuits Y, and the circuits V perform an addition process, and that the circuits Z mask either a special pixel S or an imaging pixel and do not perform addition.

In line 2 of the assumed pixel arrangement b, the circuits X are addition circuits for an imaging pixel G and an imaging pixel B, the circuits Y are addition circuits for an imaging pixel R and an imaging pixel GR, the circuits Z are addition circuits for an imaging pixel R and an imaging pixel GR, and the circuits V are addition circuits for an imaging pixel R and a special pixel S.

Consequently, for a row having a special pixel in line 2, control is exercised so that the circuits X, the circuits Y, and the circuits Z perform an addition process, and that the circuits V mask either a special pixel S or an imaging pixel and do not perform addition.

It is to be noted that, in any case, for a row having no special pixel, control exercised so that all the circuits perform an addition process.

Even if the disposition of special pixels varies from one line to another, the above-described configuration makes it easy to switch from one to another of two different pixel arrangements simply by changing pixels and register settings and without switching from an analog circuit to a logic circuit or vice versa.

It is to be noted that the special pixels S represent functionality of various special pixels to be embedded in imaging pixels, such as a focus pixel, a polarization pixel, and an IR pixel. The present technology is applicable to any special pixels as far as they are regularly disposed, and is capable of achieving the above-described configuration.

Further, the present technology has been described on the assumption that it is applied to a CMOS solid-state imaging device. However, the present technology may be applied, for example, to a CCD (Charge Coupled Device) solid-state imaging device.

### 2. Second Embodiment (Exemplary Uses of Image Sensor)

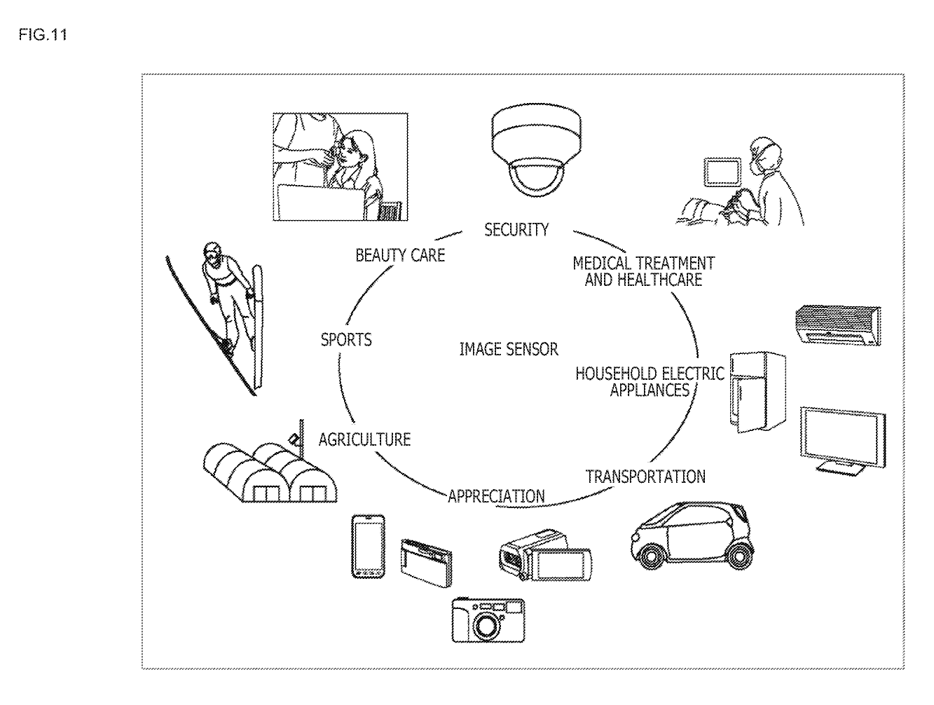

FIG. 11 is a diagram illustrating exemplary uses of the above-described solid-state imaging device.

The above-described solid-state imaging device (image sensor) can be used in various cases where, for example, visible light, infrared light, ultraviolet light, X-radiation, or other light are to be sensed as described below.
An apparatus used to capture an image for appreciation, such as a digital camera or a mobile apparatus with a camera function
An apparatus used for transportation, such as a vehicle-mounted sensor for capturing an image showing, for instance, a forward or rearward view from a vehicle, a view around the vehicle, or the interior of the vehicle in order, for example, to provide an automatic stop feature and other safety driving features and recognize the status of a driver of the vehicle, a monitoring camera for monitoring traveling vehicles and roads, or a distance sensor for measuring, for example, an inter-vehicle distance
An apparatus used with a TV set, a refrigerator, an air conditioner, or other household electric appliance in order to capture an image of a user's gesture and operate such an electric appliance in accordance with the gesture
An apparatus used with an endoscope, an angiographic instrument adapted to receive infrared light, or other medical treatment or healthcare instrument
An apparatus used for security purposes, such as a monitoring camera for crime prevention or a camera for personal authentication
An apparatus used for beauty care, such as a skin measuring instrument for capturing an image of skin or a microscope for capturing an image of a scalp
An apparatus used for sports, such as an action camera or a wearable camera for sporting and other events
An apparatus used for agriculture, such as a camera for monitoring the status of farms and farm products

### 3. Third Embodiment (Example of Electronic Apparatus)

<Exemplary Configuration of Electronic Apparatus>

The present technology is applicable not only to a solid-state imaging device but also to an image pickup device. Here, the image pickup device is a camera system for a digital still camera or a digital video camera or a mobile phone or other electronic apparatus having an imaging function. It is to be noted that the image pickup device may also be a camera module, that is, a module incorporated in an electronic apparatus.

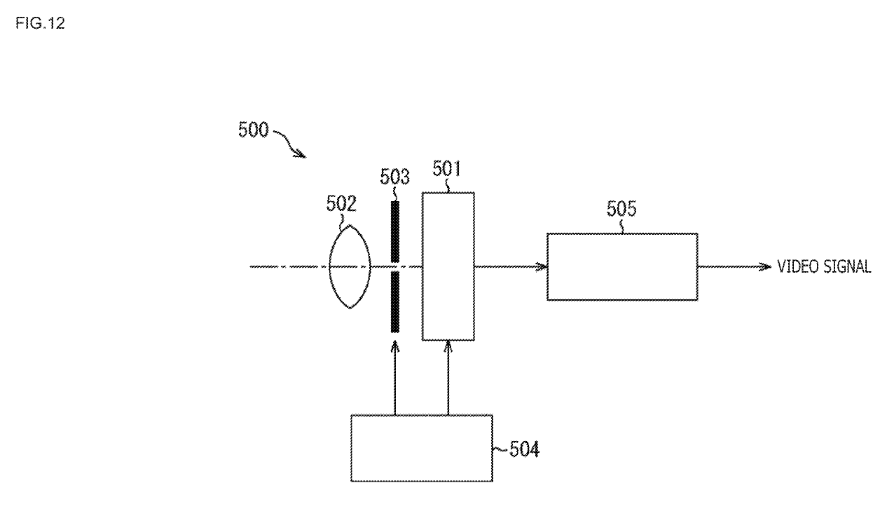

An exemplary configuration of the electronic apparatus according to the present technology will now be described with reference to FIG. 12.

An electronic apparatus 500 illustrated in FIG. 12 includes a solid-state imaging device (element chip) 501, an optical lens 502, a shutter device 503, a drive circuit 504, and a signal processing circuit 505. The earlier-described solid-state imaging device 1 according to the first embodiment of the present technology is provided as the solid-state imaging device 501. This makes it possible to reduce the power consumption of the solid-state imaging device 501 in the electronic apparatus 500, increase the accuracy of interpolation, and flexibly switch between functions (special pixel output and imaging pixel output).

The optical lens 502 receives image light (incident light) from an object and forms its image on the imaging plane of the solid-state imaging device 501. A signal electrical charge is then stored in the solid-state imaging device 501 for a predetermined period of time. The shutter device 503 controls a light irradiation period and light shielding period for the solid-state imaging device 501.

The drive circuit 504 supplies drive signals for controlling a signal transfer operation of the solid-state imaging device 501 and a shutter operation of the shutter device 503. The solid-state imaging device 501 transfers a signal in accordance with a drive signal (timing signal) supplied from the drive circuit 504. The signal processing circuit 505 performs various signal processes on signals output from the solid-image imaging device 501. A processed video signal is then stored in a memory or other storage medium or output to a monitor.

It is to be noted that, in the present specification, the steps that describe a series of processes described above not only include processes that are performed in a described chronological order, but also include processes that are performed parallelly or individually and not necessarily performed in a chronological order.

Further, the embodiments of the present disclosure are not limited to the foregoing embodiments. The foregoing embodiments may be variously modified without departing from the spirit and scope of the present disclosure.

Also, the configuration explained above as one device (or processing section) may be divided and configured as plural devices (or processing sections). Conversely, the configuration explained above as plural devices (or processing sections) may be combined and configured as one device (or processing section). Further, a configuration other described above may obviously be added to the configuration of each device (or each processing section). Furthermore, a part of the configuration of a certain device (or processing section) may be included in the configuration of another device (or another processing section) as far as the configuration and operation of the whole system are substantially the same. That is to say, the present technology is not limited to the foregoing embodiments, and various changes may be made without departing from the spirit of the present technology.

While preferred embodiments of the present disclosure have been described in detail with reference to the accompanying drawings, the present disclosure is not limited to the described preferred embodiments. It is obvious that various changes and modifications can be contemplated by those skilled in the art without departing from the scope of technical ideas described in the appended claims. It will be understood that those changes and modifications are obviously within the technical scope of the present disclosure.

It is to be noted that the present technology may adopt the following configurations.

(1) A solid-state imaging device including:

pixels that are arrayed regularly in a two-dimensional manner; and

a vertical addition circuit that, at a time of vertical addition, outputs only either one of pixels to be vertically added if one of the pixels to be vertically added is a special pixel having a function other than imaging.

(2) The solid-state imaging device as described in (1) above, in which, if one of the pixels to be vertically added is the special pixel, the vertical addition circuit masks a pixel to be not output and outputs either one of the pixels to be vertically added.

(3) The solid-state imaging device as described in (1) or (2) above, in which, if the pixels to be vertically added are both imaging pixels having an imaging function, the vertical addition circuit performs vertical addition.

(4) The solid-state imaging device as described in (1) or (2) above, in which, before performing vertical addition, the vertical addition circuit horizontally divides into at least a circuit where the special pixel is disposed and a circuit where the special pixel is not disposed.

(5) The solid-state imaging device as described in (4) above, in which, for a row where the special pixel is disposed, the vertical addition circuit performs vertical addition on a circuit where the special pixel is not disposed, and selects, as an output target, only a circuit where the special pixel is disposed, and outputs only either one of the pixels to be vertically added.

(6) The solid-state imaging device as described in (4) above, in which, for a row where the special pixel is not disposed, the vertical addition circuit performs vertical addition on a circuit where the special pixel is not disposed and on a circuit where the special pixel is disposed.

(7) An electronic apparatus including:

a solid-state imaging device that includes pixels and a vertical addition circuit, the pixels being arrayed regularly in a two-dimensional manner, and at a time of vertical addition, the vertical addition circuit outputting only either one of pixels to be vertically added if one of the pixels to be vertically added is a special pixel having a function other than imaging;

a signal processing circuit that processes an output signal output from the solid-state imaging device; and an optical system that allows incident light to enter the solid-state imaging device.

### REFERENCE SIGNS LIST

1 Solid-state imaging device, 2 Pixel, 4 Vertical drive circuit, 9 Vertical signal line, 20 Vertical addition circuit, 21 Logic circuit, 31 Adder, 32, 33 Selector, 500 Electronic apparatus, 501 Solid-state imaging device, 502 Optical lens, 503 Shutter device, 504 Drive circuit, 505 Signal processing circuit

1. A solid-state imaging device comprising:
pixels that are arrayed regularly in a two-dimensional manner; and
a vertical addition circuit that, at a time of vertical addition, outputs only either one of pixels to be vertically added if one of the pixels to be vertically added is a special pixel having a function other than imaging.

2. The solid-state imaging device according to claim 1,
wherein, if one of the pixels to be vertically added is the special pixel, the vertical addition circuit masks a pixel to be not output and outputs either one of the pixels to be vertically added.

3. The solid-state imaging device according to claim 2
wherein, if the pixels to be vertically added are both imaging pixels having an imaging function, the vertical addition circuit performs vertical addition.

4. The solid-state imaging device according to claim 2,
wherein, before performing vertical addition, the vertical addition circuit horizontally divides into at least a circuit where the special pixel is disposed and a circuit where the special pixel is not disposed.

5. The solid-state imaging device according to claim 4,
wherein, for a row where the special pixel is disposed, the vertical addition circuit performs vertical addition on a circuit where the special pixel is not disposed, and selects, as an output target, only a circuit where the special pixel is disposed, and outputs only either one of the pixels to be vertically added.

6. The solid-state imaging device according to claim 4,
wherein, for a row where the special pixel is not disposed, the vertical addition circuit performs vertical addition on a circuit where the special pixel is not disposed and on a circuit where the special pixel is disposed.

7. An electronic apparatus comprising:
a solid-state imaging device that includes pixels and a vertical addition circuit, the pixels being arrayed regularly in a two-dimensional manner, and at a time of vertical addition, the vertical addition circuit outputting only either one of pixels to be vertically added if one of the pixels to be vertically added is a special pixel having a function other than imaging;
a signal processing circuit that processes an output signal output from the solid-state imaging device; and
an optical system that allows incident light to enter the solid-state imaging device.
